(19) United States
(12) Patent Application Publication
(10) Pub. No.: US 2026/0107583 A1
(43) Pub. Date: Apr. 16, 2026

(54) PHOTODETECTOR

(71) Applicants: Kabushiki Kaisha Toshiba, Kawasaki-shi (JP); National Institute for Materials Science, Tsukuba (JP)

(72) Inventors: Rei HASHIMOTO, Edogawa Tokyo (JP); Shinji SAITO, Yokohama Kanagawa (JP); Takafumi KOZAKAI, Ota Tokyo (JP); Kazuaki SAKODA, Tsukuba Ibaraki (JP); Takashi KURODA, Tsukuba Ibaraki (JP); Tsutomu KAKUNO, Fujisawa Kanagawa (JP); Kei KANEKO, Yokohama Kanagawa (JP); Masatoshi HIRONO, Yokohama Kanagawa (JP); Tetsuya MIYAGAWA, Yokohama Kanagawa (JP)

(21) Appl. No.: 19/354,656

(22) Filed: Oct. 9, 2025

(30) Foreign Application Priority Data
Oct. 16, 2024 (JP) 2024-181010

(51) Int. Cl. H10F 30/222; H10F 77/124; H10F 77/14; H10F 77/40

(52) U.S. Cl. CPC H10F 30/222; H10F 77/1248; H10F 77/146; H10F 77/413

(57) ABSTRACT

According to one embodiment, a photodetector includes a first electrode, a second electrode, and a stacked body. At least a part of the stacked body is provided between the first electrode and the second electrode. The stacked body includes a photoelectric conversion layer being along a first plane, and an optical member. The photoelectric conversion layer is between the first electrode and the second electrode in a first direction crossing the first plane. A direction from the photoelectric conversion layer to the optical member is along the first direction. The optical member includes a first optical layer. The first optical layer includes a plurality of first regions aligned along the first plane, and a first intermediate region between the plurality of first regions. A first region refractive index of the plurality of first regions is different from a first intermediate region refractive index of the first intermediate region.

### CROSS-REFERENCE TO RELATED APPLICATIONS

This application is based upon and claims the benefit of priority from Japanese Patent Application No. 2024-181010, filed on Oct. 16, 2024; the entire contents of which are incorporated herein by reference.

### FIELD

Embodiments described herein relate generally to a photodetector.

### BACKGROUND

For example, there is a photodetector including a photoelectric conversion layer. It is desirable for the photodetector to be able to detect the target light with high sensitivity.

### BRIEF DESCRIPTION OF THE DRAWINGS

FIGS. 1A and 1B are schematic views illustrating a photodetector according to the first embodiment;

FIG. 2 is a schematic plan view illustrating a part of the photodetector according to the first embodiment;

FIG. 3 is a schematic cross-sectional view illustrating a photodetector according to the first embodiment;

FIG. 4 is a schematic cross-sectional view illustrating a photodetector according to a second embodiment;

FIG. 5 is a schematic cross-sectional view illustrating a photodetector according to the second embodiment;

FIG. 6 is a schematic cross-sectional view illustrating a photodetector according to the second embodiment; and

FIG. 7 is a schematic cross-sectional view illustrating a photodetector according to the second embodiment.

### DETAILED DESCRIPTION

According to one embodiment, a photodetector includes a first electrode, a second electrode, and a stacked body. At least a part of the stacked body is provided between the first electrode and the second electrode. The stacked body includes a photoelectric conversion layer being along a first plane, and an optical member. The photoelectric conversion layer is between the first electrode and the second electrode in a first direction crossing the first plane. A direction from the photoelectric conversion layer to the optical member is along the first direction. The optical member includes a first optical layer. The first optical layer includes a plurality of first regions aligned along the first plane, and a first intermediate region between the plurality of first regions. A first region refractive index of the plurality of first regions is different from a first intermediate region refractive index of the first intermediate region.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

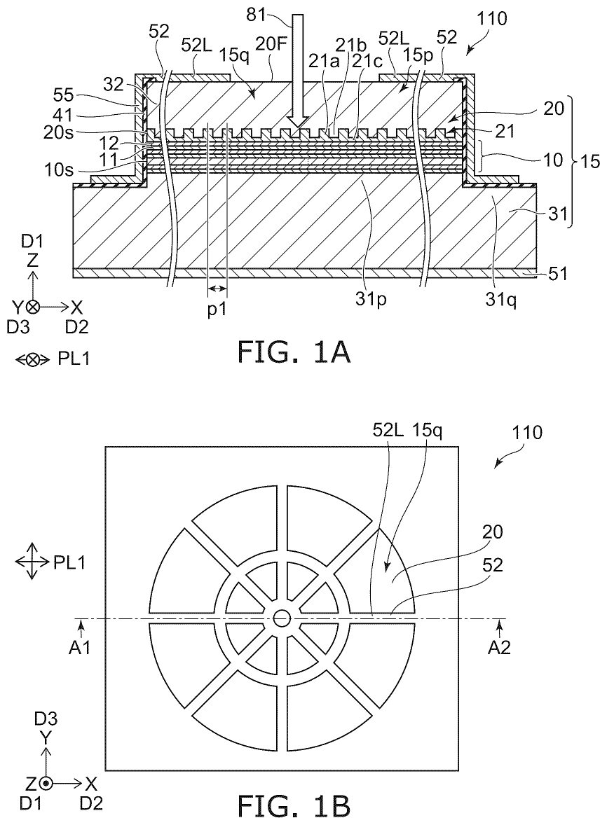

FIGS. 1A and 1B are schematic views illustrating a photodetector according to the first embodiment.

FIG. 1B is a plan view. FIG. 1A is a cross-sectional view taken along the line A1-A2 in FIG. 1B.

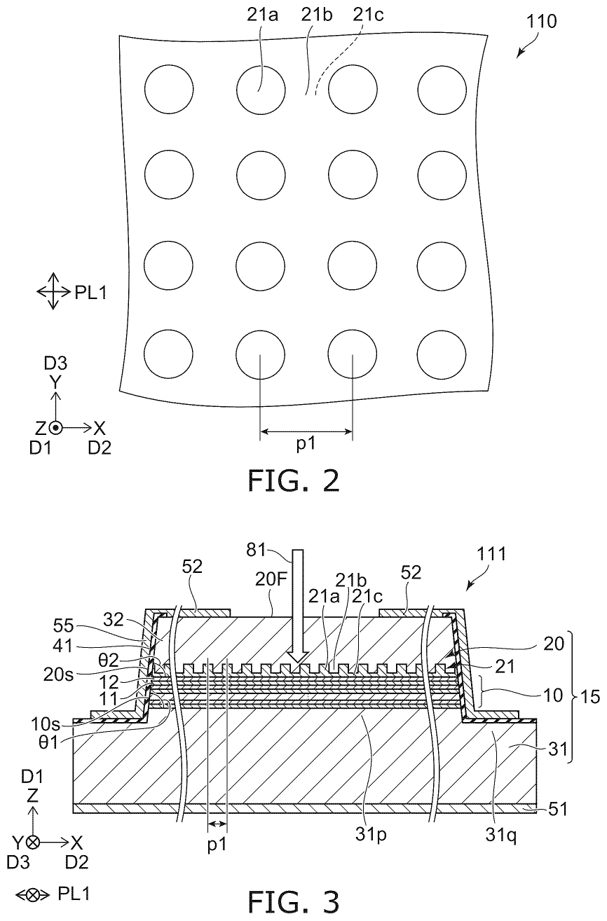

FIG. 2 is a schematic plan view illustrating a part of the photodetector according to the first embodiment.

As shown in FIG. 1A, a photodetector 110 according to the embodiment includes a first electrode 51, a second electrode 52, and a stacked body 15.

At least a part of the stacked body 15 is provided between the first electrode 51 and the second electrode 52. The stacked body 15 includes a photoelectric conversion layer 10 and an optical member 20. The stacked body 15 may include other layers (e.g., a first semiconductor layer 31, etc.). Examples of the other layers will be described later.

The photoelectric conversion layer 10 is along a first plane PL1. One direction along the first plane PL1 is defined as an X-axis direction. A direction along the first plane PL1 and perpendicular to the X-axis direction is defined as a Y-axis direction. A direction perpendicular to the X-axis and Y-axis directions is defined as a Z-axis direction.

The optical member 20 extends along the first plane PL1. The photoelectric conversion layer 10 extends along the first plane PL1.

The photoelectric conversion layer 10 is located between the first electrode 51 and the second electrode 52 in a first direction D1. The first direction D1 crosses the first plane PL1. The first direction D1 may be, for example, the Z-axis direction.

A direction from the photoelectric conversion layer 10 to the optical member 20 is along the first direction D1. The optical member 20 is stacked with the photoelectric conversion layer 10.

The optical member 20 includes a first optical layer 21. The first optical layer 21 includes a plurality of first regions 21a and a first intermediate region 21b. As shown in FIG. 2, the plurality of first regions 21a are aligned along a first plane PL1. The first intermediate region 21b is between the plurality of first regions 21a.

In this example, a plurality of first regions 21a being island-shaped are provided. The first intermediate region 21b is continuous.

In the embodiment, at least a part of the plurality of first regions 21a may be continuous. For example, one first region 21a and another first region 21a may be arranged in one direction (e.g., the second direction D2) along the first plane PL1. For example, the first intermediate region 21b may be island-shaped.

A first region refractive index of the plurality of first regions 21a is different from a first intermediate region refractive index of the first intermediate region 21b. The plurality of first regions 21a and the first intermediate region 21b may be crystals. The plurality of first regions 21a and the first intermediate region 21b may include a semiconductor. The first optical layer 21 functions, for example, as a photonic crystal layer.

For example, the first electrode 51 is electrically connected to the photoelectric conversion layer 10. The second electrode 52 is electrically connected to the optical member 20. The electrical signal generated between the first electrode 51 and the second electrode 52 is configured to change according to light 81 (detection target light) incident on the optical member 20. The light 81 may be, for example, laser light.

For example, the optical member 20 includes light incidence face 20F. The light 81 enters optical member 20 from the light incidence face 20F. For example, the light 81 may be incident substantially perpendicularly to light incidence face 20F. High incidence efficiency is obtained.

The light 81 incident on optical member 20 propagates through the optical member 20 along the first plane PL1. The light 81 spreads along the first plane PL1. The light 81 being spread is incident on the photoelectric conversion layer 10, and mobile carriers are generated in the photoelectric conversion layer 10. The light 81 can be detected by extracting the carriers via the first electrode 51 and the second electrode 52. A bias voltage may be applied to the first electrode 51 and the second electrode 52.

For example, the electric field of the light 81 incident on the light incidence face 20F along the first direction D1 includes a component perpendicular to the first direction D1. The light 81 incident on the optical member 20 propagates along the first plane PL1. The electric field of the propagating light 81 includes a component perpendicular to the first plane PL1. Such light 81 is efficiently absorbed in the photoelectric conversion layer 10, generating carriers. Efficient photoelectric conversion is obtained. For example, the light 81 can be detected with high sensitivity. According to the embodiment, a photodetector that can achieve high sensitivity can be provided.

In the embodiment, the photoelectric conversion layer 10 may include a plurality of first compound layers 11 and a plurality of second compound layers 12. One of the plurality of first compound layers 11 is between one of the plurality of second compound layers 12 and another one of the plurality of second compound layers 12 in the first direction D1. One of the plurality of second compound layers 12 is between one of the plurality of first compound layers 11 and another one of the plurality of first compound layers 11 in the first direction D1. For example, the first compound layers 11 and the second compound layers 12 may be arranged alternately in the first direction D1.

The first compound layers 11 include, for example, In_{z1}Ga_{1-z1}As (0<z1<1). The second compound layers 12 include, for example, In_{y1}Al_{1-y1}As (0<y1<1). These compound layers are semiconductor crystal layers.

The photoelectric conversion layer 10 includes, for example, a quantum cascade active layer. In the photoelectric conversion layer 10, subband transition of carriers occurs. Efficient photoelectric conversion is obtained.

In the embodiment, the light 81 may be, for example, infrared light. The wavelength of the light 81 may be, for example, not less than 3 μm and not more than 16 μm. For example, the substance to be detected may be a gas. The change in the light 81 based on absorption in the gas may be detected by the photodetector 110.

In the embodiment, the first regions 21a may include Inₓ₁Ga₁₋ₓ₁As (0<x1<1). The first intermediate region 21b may include InP. These regions may be semiconductor crystals. A large refractive index difference can be stably obtained.

In this way, the optical member 20 includes a semiconductor. As a result, the electric field applied between the first electrode 51 and the second electrode 52 is applied to the photoelectric conversion layer 10 via the optical member 20. Carriers are efficiently extracted.

As shown in FIG. 1A, the first optical layer 21 may further include a first continuous region 21c. The first continuous region 21c extends along the first plane PL1. The first continuous region 21c is between the photoelectric conversion layer 10 and the plurality of first regions 21a, and between the photoelectric conversion layer 10 and the first intermediate region 21b. A first continuous region refractive index of the first continuous region 21c may be the same as the first region refractive index of the plurality of first regions 21a. For example, the material of the first continuous region 21c may be substantially the same as the material of the plurality of first regions 21a.

As shown in FIG. 1A, the stacked body 15 may include a first semiconductor layer 31. The first semiconductor layer 31 includes a first partial region 31p and a second partial region 31q. A direction from the first partial region 31p to the second partial region 31q crosses the first direction D1. The photoelectric conversion layer 10 is between the first partial region 31p and the optical member 20 in the first direction D1. The photoelectric conversion layer 10 does not overlap the second partial region 31q in the first direction D1. The first partial region 31p may be, for example, at least a part of a mesa region. The photoelectric conversion layer 10 may be included in the mesa region. The optical member 20 may be included in the mesa region. The first semiconductor layer 31 may include, for example, a substrate. The first semiconductor layer 31 may include, for example, InP.

As shown in FIGS. 1A and 1B, the second electrode 52 may include a linear region 52L. The linear region 52L extends along the first plane PL1. The linear region 52L is provided along the light incidence face 20F. The stacked body 15 includes an overlapping region 15p and a non-overlapping region 15q. The overlapping region 15p overlaps the linear region 52L in the first direction D1. The non-overlapping region 15q does not overlap the linear region 52L in the first direction D1. The non-overlapping region 15q is not covered by the linear region 52L.

The light 81 may be attenuated in linear region 52L. The light 81 may be reflected by linear region 52L. The light 81 may not substantially pass through linear region 52L. The light 81 may be incident on the non-overlapping region 15q and then incident on photoelectric conversion layer 10. The linear region 52L allows the electric field to be applied effectively over a wide area, and carriers are extracted efficiently.

A plurality of linear regions 52L may be provided. A direction in which one of the plurality of linear regions 52L extends may cross a direction in which another one of the plurality of linear regions 52L extends. One of the plurality of linear regions 52L may extend along the second direction D2. Another one of the plurality of linear regions 52L may extend along a third direction D3. The third direction D3 crosses a plane including the first direction D1 and the second direction D2. The second direction D2 may be the X-axis direction. The third direction D3 may be the Y-axis direction.

As shown in FIG. 1A, the photodetector 110 may further include a reflective member 55. The photoelectric conversion layer 10 includes a photoelectric conversion layer side face 10s. The photoelectric conversion layer side face 10s crosses the first plane PL1. At least a part of the reflective member 55 faces the photoelectric conversion layer side face 10s. The reflective member 55 may be continuous with the second electrode 52. The reflective member 55 may be formed of a film that becomes the second electrode 52. The reflective member 55 may include the same material as the material of the second electrode 52. The reflective member 55 may be conductive.

The photodetector 110 may further include an insulating member 41. At least a part of the insulating member 41 is provided between the photoelectric conversion layer 10 and the reflective member 55.

The optical member 20 includes an optical member side face 20s. The optical member side face 20s crosses the first plane PL1. A part of the reflective member 55 may face the optical member side face 20s. The insulating member 41 is provided between the photoelectric conversion layer 10 and the reflective member 55.

The light 81 incident on the optical member 20 can efficiently enter the photoelectric conversion layer 10. Higher sensitivity can be obtained by using the reflective member 55.

A first pitch p1 in the first plane PL1 of the plurality of first regions 21a may be, for example, not less than 1000 nm and not more than 5000 nm. The travel direction of the light 81 can be changed efficiently. The first pitch p1 may be, for example, a length along the second direction D2.

The length (thickness) of one of the plurality of first regions 21a along the second direction D2 may be, for example, not less than 0.1 μm and not more than 4.5 μm. The distance along the second direction D2 between one of the plurality of first regions 21a and another one of the plurality of first regions 21a may be not less than 0.2 μm and not more than 4.5 μm. One of the plurality of first regions 21a is next to another one of the plurality of first regions 21a.

In the example shown in FIG. 2, the planar shape of each of the plurality of first regions 21a is circular. A circular shape includes a circular shape or a flattened circular shape. The planar shape of each of the plurality of first regions 21a may be polygonal. The number of corners included in the polygon may be four or more. The number may be five or more. The corners of the polygon may be curved.

As shown in FIG. 1A, the optical member 20 may include a second semiconductor layer 32. The first optical layer 21 is between the photoelectric conversion layer 10 and the second semiconductor layer 32. The second semiconductor layer 32 may include the same material as the material of the first intermediate region 21b.

FIG. 3 is a schematic cross-sectional view illustrating a photodetector according to the first embodiment.

As shown in FIG. 3, in a photodetector 111 according to the embodiment, the optical member side face 20s is tapered. Except for this, the configuration of the photodetector 111 may be the same as the configuration of the photodetector 110.

In the photodetector 111, the optical member side face 20s is inclined with respect to the first plane PL1. The photodetector 111 includes the reflective member 55. At least a part of the reflective member 55 faces the optical member side face 20s. The tapered side face allows the light 81 to efficiently enter the photoelectric conversion layer 10. Efficient detection is possible.

In the photodetector 111, the photoelectric conversion layer 10 may include the photoelectric conversion layer side face 10s that is inclined with respect to the first plane PL1. At least a part of the reflective member 55 faces the photoelectric conversion layer side face 10s. As the photoelectric conversion layer side face 10s is inclined with respect to the first plane PL1, the traveling direction of a part of the light 81 is likely to change. The light 81 is efficiently converted into an electrical signal.

At least a part of the insulating member 41 may be provided between the photoelectric conversion layer 10 and the reflective member 55. At least a part of the insulating member 41 may be provided between the optical member 20 and the reflective member 55.

A first angle θ1 between the first plane PL1 and the photoelectric conversion layer side face 10s may be, for example, not less than 60 degrees and not more than 89 degrees. A second angle θ2 between the first plane PL1 and the optical member side face 20s may be, for example, not less than 60 degrees and not more than 89 degrees. The first angle θ1 may be smaller than the second angle θ2. Higher efficiency is easier to be obtained.

### Second Embodiment

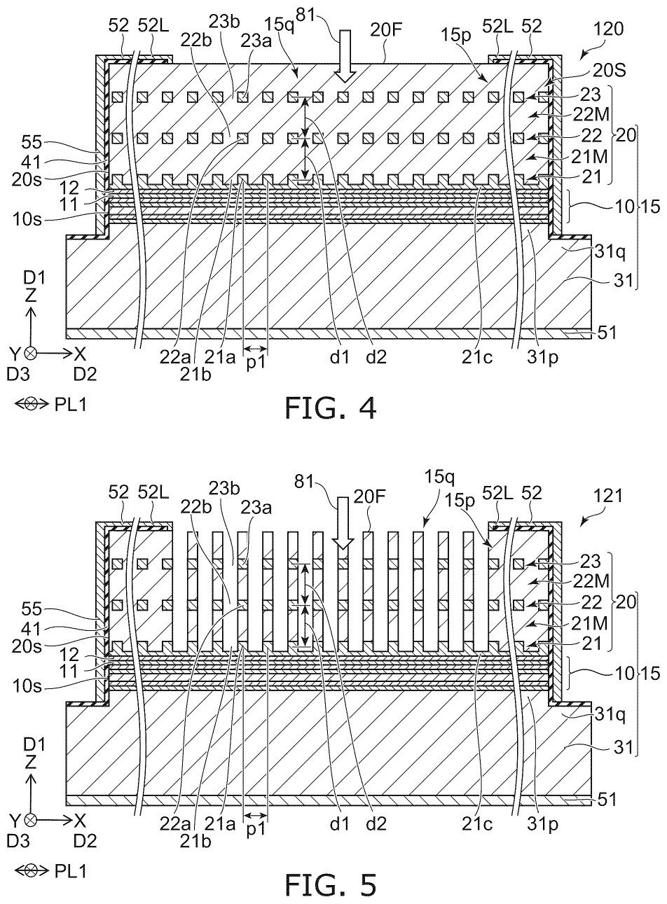

FIG. 4 is a schematic cross-sectional view illustrating a photodetector according to a second embodiment.

As shown in FIG. 4, in a photodetector 120 according to the embodiment, the optical member 20 includes a plurality of optical layers. Except for this, the configuration of the photodetector 120 may be the same as the configuration of the photodetector 110 or the photodetector 111.

In the photodetector 120, the optical member 20 further includes a second optical layer 22 in addition to the first optical layer 21. The second optical layer 22 includes a plurality of second regions 22a and a second intermediate region 22b. The plurality of second regions 22a are aligned along the first plane PL1. The second intermediate region 22b is between the plurality of second regions 22a. A second region refractive index of the plurality of second regions 22a is different from a second intermediate region refractive index of the second intermediate region 22b. A direction from one of the plurality of first regions 21a to one of the plurality of second regions 22a is along the first direction D1.

The second optical layer 22 functions as a photonic crystal layer. By providing the second optical layer 22 in addition to the first optical layer 21, the light 81 can be more effectively propagated in the direction along the first plane PL1. Highly efficient photoelectric conversion is obtained in the photoelectric conversion layer 10.

The shape of each of the plurality of second regions 22a may be the same as the shape of each of the plurality of first regions 21a. The pitch of the plurality of second regions 22a may be the same as the first pitch p1 of the plurality of first regions 21a. The plurality of second regions 22a overlap the plurality of first regions 21a in the first direction D1. The second intermediate region 22b overlaps the first intermediate region 21b in the first direction D1.

As shown in FIG. 4, the optical member 20 may include a first interlayer region 21M. The first interlayer region 21M is between the first optical layer 21 and the second optical layer 22. For example, a first interlayer region refractive index of the first interlayer region 21M is different from the second region refractive index of the plurality of second regions 22a.

The refractive index is different between the plurality of first regions 21a and the first interlayer region 21M. The refractive index is different between the plurality of second regions 22a and the first interlayer region 21M. The difference in refractive index effectively changes the propagation direction of light 81.

For example, in the first optical layer 21, the difference in refractive index at the interface between the plurality of first regions 21a and the first intermediate region 21b is utilized. In the second optical layer 22, the difference in refractive index at the interface between the plurality of second regions 22a and the second intermediate region 22b is utilized. These interfaces cross the first plane PL1.

The difference in refractive index at the interfaces between the plurality of first regions 21a and the first interlayer region 21M is utilized. The difference in refractive index at the interfaces between the plurality of second regions 22a and the first interlayer region 21M is utilized. These interfaces are along the first plane PL1. The difference in refractive index at the interfaces that cross the first plane PL1 and the interfaces along the first plane PL1 is utilized. Higher sensitivity is obtained.

The first interlayer region refractive index of the first interlayer region 21M may be the same as the refractive index of the first intermediate region 21b. The second region refractive index of the plurality of second regions 22a may be the same as the first region refractive index of the plurality of first regions 21a. The second intermediate region refractive index of the second intermediate region 22b may be the same as the first intermediate region refractive index of the first intermediate region 21b. The first interlayer region 21M may be provided between the first intermediate region 21b and the second intermediate region 22b. The boundary between these regions may be clear or unclear.

The second regions 22a may include Inₓ₂Ga₁₋ₓ₂As (0<x2<1). The second intermediate region 22b may include InP. The composition ratio x2 may be the same as or different from the composition ratio x1.

A distance between a first center in the first direction D1 of one of the first regions 21a and a second center in the first direction D1 of one of the second regions 22a is defined as a first distance d1. The first pitch p1 of the first regions 21a on the first plane PL1 may be not less than 0.5 times and not more than 7 times the first distance d1. Higher sensitivity can be obtained.

In the embodiment, the number of optical layers may be three or more. For example, the optical member 20 may further include a third optical layer 23. The optical member 20 may further include a second interlayer region 22M. The second interlayer region 22M is between the second optical layer 22 and the third optical layer 23.

The third optical layer 23 includes a plurality of third regions 23a and a third intermediate region 23b. The plurality of third regions 23a are aligned along the first plane PL1. The third intermediate region 23b is between the plurality of third regions 23a. A third region refractive index of the plurality of third regions 23a is different from a third intermediate region refractive index of the third intermediate region 23b. A direction from one of the plurality of second regions 22a to one of the plurality of third regions 23a is along the first direction D1. The plurality of third regions 23a overlap the plurality of second regions 22a in the first direction D1. The third intermediate region 23b overlaps the second intermediate region 22b in the first direction D1.

The third optical layer 23 functions as a photonic crystal layer. The light 81 can propagate more effectively in the direction along the first plane PL1. More efficient photoelectric conversion can be obtained in the photoelectric conversion layer 10.

A second interlayer region refractive index of the second interlayer region 22M is different from the third region refractive index of the plurality of third regions 23a. The difference in refractive index is utilized at the interface between the plurality of third regions 23a and the second interlayer region 22M. The second interlayer region refractive index of the second interlayer region 22M is different from the second region refractive index of the plurality of second regions 22a. The difference in refractive index is utilized at the interface between the plurality of second regions 22a and the second interlayer region 22M. Efficient detection is possible. Highly sensitive detection is possible.

The second interlayer region refractive index of the second interlayer region 22M may be the same as the second intermediate region refractive index of the second intermediate region 22b.

The plurality of third regions 23a may include Inₓ₃Ga₁₋ₓ₃As (0<x3<1). The third intermediate region 23b may include InP. The composition ratio x3 may be the same as or different from the composition ratio x1. The composition ratio x3 may be the same as or different from the composition ratio x2.

A distance between the second center in the first direction D1 of one of the second regions 22a and a third center in the first direction D1 of one of the third regions 23a is defined as a second distance d2. The first pitch p1 in the first plane PL1 of the first regions 21a may be not less than 0.5 times and not less than 7 times the second distance d2. Higher sensitivity can be obtained.

In the embodiment, by providing plurality of optical layers, the propagation direction of light 81 can be efficiently converted to a direction along the first direction D1. The direction of the electric field of the light 81 can be efficiently converted to a direction crossing the first plane PL1. For example, the directionality (or the controllability of the directionality) of the detection characteristics of the incident light 81 can be improved.

The plurality of first regions 21a may be arranged two-dimensionally along the first plane PL1. The plurality of second regions 22a may be arranged two-dimensionally along the first plane PL1. The plurality of third regions 23a may be arranged two-dimensionally along the first plane PL1.

FIG. 5 is a schematic cross-sectional view illustrating a photodetector according to the second embodiment.

As shown in FIG. 5, in a photodetector 121 according to the embodiment, the configuration of the optical member 20 is different from that in the photodetector 120. Except for this, the configuration of the photodetector 121 may be the same as the configuration of the photodetector 120.

In the photodetector 121, the first intermediate region 21b includes a gas. The gas may include air, etc. The first regions 21a may include, for example, Inₓ₁Ga₁₋ₓ₁As (0<x1<1). A large difference in refractive index is obtained between the first regions 21a and the first intermediate region 21b.

The second intermediate region 22b may include a gas. The second regions 22a may include, for example, Inₓ₂Ga₁₋ₓ₂As (0<x2<1). A large difference in refractive index is obtained between the second regions 22a and the second intermediate region 22b. The third intermediate region 23b may include a gas. The third regions 23a may include, for example, Inₓ₃Ga₁₋ₓ₃As (0<x3<1). A large difference in refractive index is obtained between the third regions 23a and the third intermediate region 23b.

The second electrode 52 may include the linear region 52L extending along the first plane PL1. The stacked body 15 includes the overlapping region 15p and the non-overlapping region 15q. The overlapping region 15p overlaps the linear region 52L in the first direction D1. The non-overlapping region 15q does not overlap the linear region 52L in the first direction D1. In the photodetector 121, the first intermediate region 21b in the non-overlapping region 15q includes a gas (e.g., air). The second intermediate region 22b in the non-overlapping region 15q includes a gas. The third intermediate region 23b in the non-overlapping region 15q includes a gas.

The first intermediate region 21b in the overlapping region 15p includes a semiconductor crystal. The second intermediate region 22b in the overlapping region 15p includes a semiconductor crystal. The third intermediate region 23b in the overlapping region 15p includes a semiconductor crystal. The semiconductor crystal includes, for example, InP.

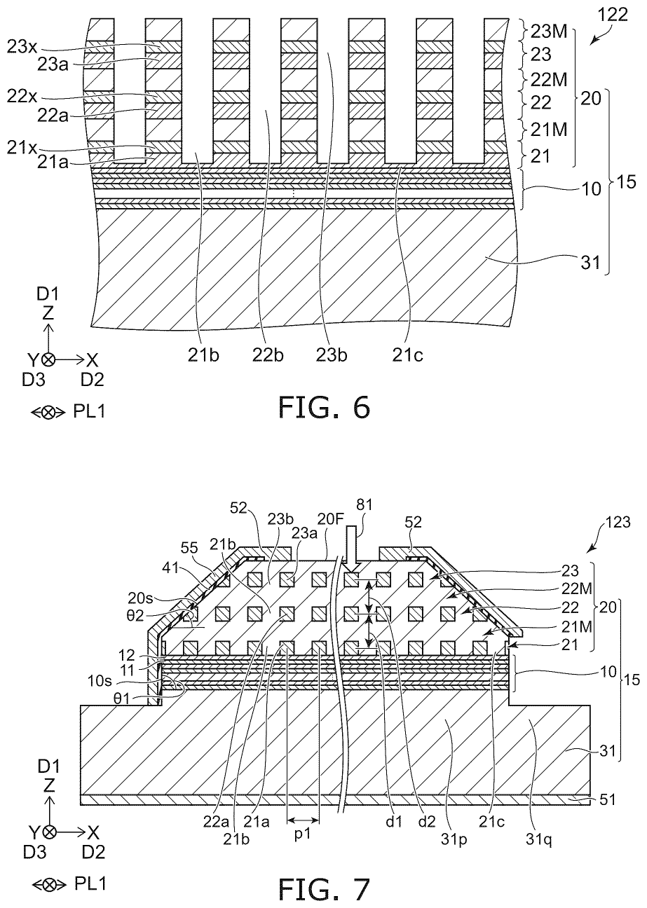

FIG. 6 is a schematic cross-sectional view illustrating a photodetector according to the second embodiment.

As shown in FIG. 6, in a photodetector 122 according to the embodiment, the configuration of the optical member 20 differs from that in the photodetector 121. Except for this, the configuration of the photodetector 122 may be the same as the configuration of the photodetector 120.

In the photodetector 122, the first optical layer 21 further includes a first intermediate layer 21x. The first intermediate layer 21x is provided between the plurality of first regions 21a and the first interlayer region 21M. The second optical layer 22 may further include a second intermediate layer 22x. The second intermediate layer 22x is provided between the plurality of second regions 22a and the second interlayer region 22M.

The third optical layer 23 may further include a third intermediate layer 23x. A plurality of third regions 23a are provided between the second interlayer region 22M and the third interlayer region 23M.

The first intermediate layer 21x, the second intermediate layer 22x, and the third intermediate layer 23x may include, for example, In_{α1}Al_{1-α1}As (0<α1<1). The first regions 21a, the second regions 22a, and the third regions 23a may include, for example, Inₓ₁Ga₁₋ₓ₁As (0<x1<1). The first interlayer region 21M, the second interlayer region 22M, and the third interlayer region 23M may include, for example, InP.

For example, deterioration of characteristics caused by the difference in lattice length between the plurality of first regions 21a and the first interlayer region 21M is suppressed. For example, adverse effects of distortion are mitigated. For example, deterioration of characteristics caused by the difference in lattice length between the plurality of second regions 22a and the second interlayer region 22M is suppressed. For example, adverse effects of distortion are mitigated.

FIG. 7 is a schematic cross-sectional view illustrating a photodetector according to the second embodiment.

As shown in FIG. 7, in a photodetector 123 according to the embodiment, the configuration of the optical member 20 is different from that in the photodetector 120. Except for this, the configuration of the photodetector 123 may be the same as the configuration of the photodetector 120.

In the photodetector 123, the optical member side face 20s is inclined with respect to the first plane PL1. The photodetector 123 includes the reflective member 55. At least a part of the reflective member 55 faces the optical member side face 20s. The tapered side face allows the light 81 to efficiently enter the photoelectric conversion layer 10. Efficient detection is possible.

In the photodetector 123, the photoelectric conversion layer 10 may include a photoelectric conversion layer side face 10s that is inclined with respect to the first plane PL1. At least a part of the reflective member 55 faces the photoelectric conversion layer side face 10s. The inclination of the photoelectric conversion layer side face 10s with respect to the first plane PL1 changes the traveling direction of a part of the light 81. The light 81 is efficiently converted into an electrical signal.

At least a part of the insulating member 41 may be provided between the photoelectric conversion layer 10 and the reflective member 55. At least a part of the insulating member 41 may be provided between the optical member 20 and the reflective member 55.

The first angle θ1 between the first plane PL1 and the photoelectric conversion layer side face 10s may be, for example, not less than 60 degrees and not more than degrees. The second angle θ2 between the first plane PL1 and the optical member side face 20s may be, for example, not less than 60 degrees and not more than 89 degrees. The first angle θ1 may be smaller than the second angle θ2. Higher efficiency is easier to obtain.

For example, a film that will become the plurality of first regions 21a is formed, and a part of the film is removed to obtain the plurality of first regions 21a. The region obtained by the removal is filled with a material that will become the first intermediate region 21b, to obtain the first intermediate region 21b. For example, the formation of a first film that will become the plurality of first regions 21a and the formation of a second film that will become the first interlayer region 21M may be repeated. After that, portions of plurality of sets of structures including the first film and the second film may be removed all at once. For example, dry etching may be performed in the removal. A highly accurate shape is obtained.

The embodiment may include the following Technical proposals:

### Technical Proposal 1

A photodetector, comprising:
a first electrode;
a second electrode; and
a stacked body, at least a part of the stacked body being provided between the first electrode and the second electrode,
the stacked body including
a photoelectric conversion layer being along a first plane, and
an optical member,
the photoelectric conversion layer being between the first electrode and the second electrode in a first direction crossing the first plane,
a direction from the photoelectric conversion layer to the optical member being along the first direction,
the optical member including a first optical layer,
the first optical layer including:
a plurality of first regions aligned along the first plane, and
a first intermediate region between the plurality of first regions,
a first region refractive index of the plurality of first regions being different from a first intermediate region refractive index of the first intermediate region.

### Technical Proposal 2

The photodetector according to Technical proposal 1, wherein
the optical member further includes a second optical layer,
the second optical layer includes:
a plurality of second regions aligned along the first plane, and
a second intermediate region between the plurality of second regions,
a second region refractive index of the plurality of second regions is different from a second intermediate region refractive index of the second intermediate region, and
a direction from one of the plurality of first regions to one of the plurality of second regions is along the first direction.

### Technical Proposal 3

The photodetector according to Technical proposal 2, wherein
the optical member further includes a first interlayer region between the first optical layer and the second optical layer, and
a first interlayer region refractive index of the first interlayer region is different from the second region refractive index.

### Technical Proposal 4

The photodetector according to Technical proposal 2 or 3, wherein
the second region refractive index is the same as the first region refractive index, and
the second intermediate region refractive index is the same as the first intermediate region refractive index.

### Technical Proposal 5

The photodetector according to any one of Technical proposals 2-4, wherein
a first pitch of the plurality of first regions in the first plane is not less than 0.5 times and not more than 7 times a first distance between a first center of the one of the plurality of first regions in the first direction and a second center of the one of the plurality of second regions in the first direction.

### Technical Proposal 6

The photodetector according to any one of Technical proposals 2-4, wherein
the optical member further includes a third optical layer and a second interlayer region between the second optical layer and the third optical layer,
the third optical layer includes:
a plurality of third regions aligned along the first plane, and
a third intermediate region between the plurality of third regions,
a third region refractive index of the plurality of third regions is different from a third intermediate region refractive index of the third intermediate region,
a direction from one of the plurality of second regions to one of the plurality of third regions is along the first direction, and
a second interlayer region refractive index of the second interlayer region refractive index is different from the third region refractive index.

### Technical Proposal 7

The photodetector according to Technical proposal 6, wherein
a first pitch of the plurality of first regions in the first plane is not less than 0.5 time and not more than to 7 times a second distance between a second center of the one of the plurality of second regions in the first direction and a third center of the one of the plurality of third regions in the first direction.

### Technical Proposal 8

The photodetector according to any one of Technical proposals 1-7, wherein
the first optical layer further includes a first continuous region extending along the first plane,
the first continuous region is provided between the photoelectric conversion layer and the first regions, and between the photoelectric conversion layer and the first intermediate region, and
a first continuous region refractive index of the first continuous region is the same as the first region refractive index.

### Technical Proposal 9

The photodetector according to any one of Technical proposals 1-8, wherein
the stacked bod includes a first semiconductor layer,
the first semiconductor layer includes a first partial region and a second partial region,
a direction from the first partial region to the second partial region crosses the first direction,
the photoelectric conversion layer is between the first partial region and the optical member in the first direction, and
the photoelectric conversion layer does not overlap the second partial region in the first direction.

### Technical Proposal 10

The photodetector according to any one of Technical proposals 1-9, wherein
the photoelectric conversion layer includes a quantum cascade active layer.

### Technical Proposal 11

The photodetector according to any one of Technical proposals 1-10, wherein
a subband transition of carriers occurs in the photoelectric conversion layer.

### Technical Proposal 12

The photodetector according to any one of Technical proposals 1-11, wherein
the photoelectric conversion layer includes a plurality of first compound layers and a plurality of second compound layers,
one of the plurality of first compound layers is between one of the plurality of second compound layers and another one of the plurality of second compound layers,
the one of the plurality of second compound layers is between the one of the plurality of first compound layers and another one of the plurality of first compound layers,
the first compound layers include In_{z1}Ga_{1-z1}As (0<z1<1), and
the second compound layers include In_{y1}Al_{1-y1}As (0<y1<1).

### Technical Proposal 13

The photodetector according to any one of Technical proposals 1-12, wherein
the first regions include Inₓ₁Ga₁₋ₓ₁As (0<x1<1) , and
the first intermediate region includes InP.

### Technical Proposal 14

The photodetector according to any one of Technical proposals 1-12, wherein
the first regions include Inₓ₁Ga₁₋ₓ₁As (0<x1<1), and
the first intermediate region includes a gas.

### Technical Proposal 15

The photodetector according to any one of Technical proposals 1-12, wherein
the second electrode includes a linear region extending along the first plane,
the stacked body includes an overlapping region and a non-overlapping region,
the overlapping region overlaps the linear region in the first direction,
the non-overlapping region does not overlap the linear region in the first direction, and
the first intermediate region in the non-overlapping region includes gas.

### Technical proposal 16

The photodetector according to any one of Technical proposals 1-15, further comprising:
a reflective member,
the optical element including an optical element side face being inclined with respect to the first plane, and
at least a part of the reflective member facing the optical element side face.

### Technical proposal 17

The photodetector according to any one of Technical proposals 1-15, further comprising:
a reflective member,
the photoelectric conversion layer including a photoelectric conversion layer side face being inclined with respect to the first plane, and
at least a part of the reflective member facing the photoelectric conversion layer side face.

### Technical Proposal 18

The photodetector according to Technical proposal 17, further comprising:
the reflecting member is continuous with the second electrode, and
at least a part of the insulating member being provided between the photoelectric conversion layer and the reflective member.

### Technical Proposal 19

The photodetector according to any one of Technical proposals 1-18, wherein
the optical member includes a semiconductor.

### Technical Proposal 20

The photodetector according to any one of Technical proposals 1-19, wherein
an electrical signal generated between the first electrode and the second electrode is configured to change in response to light incident on the optical member.

According to an embodiment, a photodetector capable of achieving high sensitivity is provided.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the photodetectors, electrode, stacked bodies, photoelectric conversion layers, optical members, semiconductor layers, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all photodetectors practicable by an appropriate design modification by one skilled in the art based on the photodetectors described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A photodetector, comprising:
a first electrode;
a second electrode; and
a stacked body, at least a part of the stacked body being provided between the first electrode and the second electrode,
the stacked body including
a photoelectric conversion layer being along a first plane, and
an optical member,
the photoelectric conversion layer being between the first electrode and the second electrode in a first direction crossing the first plane,
a direction from the photoelectric conversion layer to the optical member being along the first direction,
the optical member including a first optical layer,
the first optical layer including:
a plurality of first regions aligned along the first plane, and
a first intermediate region between the plurality of first regions,
a first region refractive index of the plurality of first regions being different from a first intermediate region refractive index of the first intermediate region.

2. The photodetector according to claim 1, wherein
the optical member further includes a second optical layer,
the second optical layer includes:
a plurality of second regions aligned along the first plane, and
a second intermediate region between the plurality of second regions,
a second region refractive index of the plurality of second regions is different from a second intermediate region refractive index of the second intermediate region, and
a direction from one of the plurality of first regions to one of the plurality of second regions is along the first direction.

3. The photodetector according to claim 2, wherein
the optical member further includes a first interlayer region between the first optical layer and the second optical layer, and
a first interlayer region refractive index of the first interlayer region is different from the second region refractive index.

4. The photodetector according to claim 2, wherein
the second region refractive index is the same as the first region refractive index, and
the second intermediate region refractive index is the same as the first intermediate region refractive index.

5. The photodetector according to claim 2, wherein
a first pitch of the plurality of first regions in the first plane is not less than 0.5 times and not more than 7 times a first distance between a first center of the one of the plurality of first regions in the first direction and a second center of the one of the plurality of second regions in the first direction.

6. The photodetector according to claim 2, wherein
the optical member further includes a third optical layer and a second interlayer region between the second optical layer and the third optical layer,
the third optical layer includes:
a plurality of third regions aligned along the first plane, and
a third intermediate region between the plurality of third regions,
a third region refractive index of the plurality of third regions is different from a third intermediate region refractive index of the third intermediate region,
a direction from one of the plurality of second regions to one of the plurality of third regions is along the first direction, and
a second interlayer region refractive index of the second interlayer region refractive index is different from the third region refractive index.

7. The photodetector according to claim 6, wherein
a first pitch of the plurality of first regions in the first plane is not less than 0.5 time and not more than to 7 times a second distance between a second center of the one of the plurality of second regions in the first direction and a third center of the one of the plurality of third regions in the first direction.

8. The photodetector according to claim 1, wherein
the first optical layer further includes a first continuous region extending along the first plane,
the first continuous region is provided between the photoelectric conversion layer and the first regions, and between the photoelectric conversion layer and the first intermediate region, and
a first continuous region refractive index of the first continuous region is the same as the first region refractive index.

9. The photodetector according to claim 1, wherein
the stacked bod includes a first semiconductor layer,
the first semiconductor layer includes a first partial region and a second partial region,
a direction from the first partial region to the second partial region crosses the first direction,
the photoelectric conversion layer is between the first partial region and the optical member in the first direction, and
the photoelectric conversion layer does not overlap the second partial region in the first direction.

10. The photodetector according to claim 1, wherein
the photoelectric conversion layer includes a quantum cascade active layer.

11. The photodetector according to claim 1, wherein
a subband transition of carriers occurs in the photoelectric conversion layer.

12. The photodetector according to claim 1, wherein
the photoelectric conversion layer includes a plurality of first compound layers and a plurality of second compound layers,
one of the plurality of first compound layers is between one of the plurality of second compound layers and another one of the plurality of second compound layers,
the one of the plurality of second compound layers is between the one of the plurality of first compound layers and another one of the plurality of first compound layers,
the first compound layers include In_{z1}Ga_{1-z1}As (0<z1<1), and
the second compound layers include In_{y1}Al_{1-y1}As (0<y1<1).

13. The photodetector according to claim 1, wherein
the first regions include Inₓ₁Ga₁₋ₓ₁As (0<x1<1), and
the first intermediate region includes InP.

14. The photodetector according to claim 1, wherein
the first regions include Inₓ₁Ga₁₋ₓ₁As (0<x1<1), and
the first intermediate region includes a gas.

15. The photodetector according to claim 1, wherein
the second electrode includes a linear region extending along the first plane,
the stacked body includes an overlapping region and a non-overlapping region,
the overlapping region overlaps the linear region in the first direction,
the non-overlapping region does not overlap the linear region in the first direction, and
the first intermediate region in the non-overlapping region includes gas.

16. The photodetector according to claim 1, further comprising:
a reflective member,
the optical element including an optical element side face being inclined with respect to the first plane, and
at least a part of the reflective member facing the optical element side face.

17. The photodetector according to claim 1, further comprising:
a reflective member,
the photoelectric conversion layer including a photoelectric conversion layer side face being inclined with respect to the first plane, and
at least a part of the reflective member facing the photoelectric conversion layer side face.

18. The photodetector according to claim 17, further comprising:
the reflecting member is continuous with the second electrode, and
at least a part of the insulating member being provided between the photoelectric conversion layer and the reflective member.

19. The photodetector according to claim 1, wherein
the optical member includes a semiconductor.

20. The photodetector according to claim 1, wherein
an electrical signal generated between the first electrode and the second electrode is configured to change in response to light incident on the optical member.
